(19) United States
(12) Patent Application Publication
(10) Pub. No.: US 2001/0029081 A1
(43) Pub. Date: Oct. 11, 2001

(54) Method for producing semiconductor device

(75) Inventor: Takashi Yokoyama, Tokyo (JP)

Correspondence Address: YOUNG & THOMPSON, 745 SOUTH 23RD STREET 2ND FLOOR, ARLINGTON, VA, 22202

(73) Assignee: NEC Corporation

(21) Appl. No.: 09/815,037

(22) Filed: Mar. 23, 2001

(30) Foreign Application Priority Data
Mar. 24, 2000 (JP) 85082/2000

(51) Int. Cl. H01L 21/76

(52) U.S. Cl. 438/400

(57) ABSTRACT

A method for producing a semiconductor device of the present invention includes the steps of: forming an interlayer insulation film on a semiconductor substrate; forming a groove in the interlayer insulation film; forming a metal interconnect layer in the groove; forming an oxidization-resistant metal layer on an upper surface of the metal interconnect layer by an electroless plating method; and forming an oxygen-containing insulation film on an upper surface of the metal layer.

### BACKGROUND OF THE INVENTION

1. Field of the Invention

The present invention relates to a method for producing a semiconductor device and, more particularly, to a method for producing a semiconductor device having a multilayer interconnect structure.

2. Description of the Prior Art

In recent years, there has been an increasing demand for increasing the signal processing speed of LSIs. The signal processing speed of an LSI is determined primarily by the operation speed of the transistors themselves and the delay time in the signal propagation along the interconnect. The former factor, i.e., the operation speed of the transistor, was dominant in the prior art, but it has been significantly improved through downsizing of transistors. As a result, for contemporary LSIs which are made under a design rule of 0.18 μm or less, the latter factor, i.e., the delay time in the signal propagation along the interconnect, is becoming more significant.

In order to solve this problem, a metal interconnect layer made of Cu, having a small electric resistant value, has been used in place of an Al interconnect used in the prior art. FIG. 14 and FIG. 15 are cross-sectional views each illustrating a structure of a semiconductor device disclosed in Japanese Laid-Open Patent Publication No. 9-275138.

In the semiconductor device of FIG. 14, a Cu interconnect layer 6 is embedded in a groove 3 which is provided in an interlayer insulation film including a C- or F-containing insulation film 2 on a semiconductor substrate 1 and an F-containing oxidation film 4. Cu has a problem of diffusing into the interlayer insulation film, thereby causing a leak current. In this structure, however, the side surface and the bottom surface of the interconnect layer 6 are covered with a titanium nitride film 5 for preventing the Cu diffusion. Similarly, a silicon nitride film 7 is formed on the upper surface of the interconnect layer 6 for preventing the Cu diffusion into an overlying interlayer insulation film.

In the semiconductor device of FIG. 15, a barrier metal layer 5″ made of a high melting point metal is provided on the upper surface of the interconnect layer 6. The C- or F-containing insulation film 7 is formed on the barrier metal layer 5″. For the barrier metal layer 5″, an Nb film formed by a selective CVD method or a W film formed by a self-aligned precipitation method is used.

In order to form a multilayer interconnect structure, it is necessary to further provide an interlayer insulation film (not shown) on the Cu interconnect structure illustrated in FIG. 14 or FIG. 15, and to form a through hole reaching the Cu interconnect layer 6 in the interlayer insulation film in the etching step using a patterned photoresist as a mask.

In the Cu interconnect structure illustrated in FIG. 14, a through hole is formed by etching the interlayer insulation film (not shown) provided on the Cu interconnect layer and the silicon nitride film 7 using a patterned photoresist as a mask, and then, with the upper surface of the Cu interconnect layer being exposed, the photoresist is removed by an oxygen plasma process or a wet removing process using a removing solution such as amine.

However, Cu is a metal which is easily oxidized, and is oxidized to form oxidized copper, thereby increasing the interconnect resistance, if an oxygen plasma process is performed. When a wet removing process is performed, it reacts with the removing solution to form a copper compound. Since the copper compound dissolves in the removing solution, a defect such as disconnection of an interconnect occurs.

Moreover, in the Cu interconnect structure illustrated in FIG. 14, the silicon nitride film 7 is provided as a Cu diffusion prevention film. However, since a silicon nitride film has a high relative dielectric constant of 7 to 8, the propagation delay increases due to the fringe effect.

In the Cu interconnect structure illustrated in FIG. 15, the increase in the interconnect resistance or the interconnect defect is less likely to occur because the photoresist can be removed without exposing the upper surface of the Cu interconnect layer if a through hole is formed by etching the silicon nitride film 7 and the interlayer insulation film (not shown) provided on the Cu interconnect layer and the etching is stopped at the surface of the high melting point metal film.

However, it is difficult to appropriately determine the selective CVD method conditions, i.e., the type of material gas, the deposition conditions, etc., for depositing the high melting point metal with selectivity between the underlying Cu interconnect layer 6 and the interlayer insulation film 2, and such conditions are not disclosed in Japanese Laid-Open Patent Publication No. 9-275138. Moreover, it is also difficult to deposit an Nb film having a good film quality while depositing it selectively on the Cu interconnect layer.

In the method where W is precipitated in a self-aligned manner from the barrier metal layer 5 onto the side surface and the bottom surface of the Cu interconnect layer 6, W remains in the Cu interconnect layer 6, whereby the resistance of the interconnect layer as a whole is increased and the interconnect layer 6 becomes brittle.

### BRIEF SUMMARY OF THE INVENTION

### Objects of the Invention

An object of the present invention is to provide a method for producing a semiconductor device capable of preventing oxidization of a Cu interconnect layer and keeping the interconnect resistance low.

### Summary of the Invention

A method for producing a semiconductor device of the present invention includes the steps of: forming an interlayer insulation film on a semiconductor substrate; forming a groove in the interlayer insulation film; forming a metal interconnect layer in the groove; forming an oxidization-resistant metal layer on an upper surface of the metal interconnect layer by an electroless plating method; and forming an oxygen-containing insulation film on an upper surface of the metal layer.

### BRIEF DESCRIPTION OF THE DRAWINGS

The above-mentioned and other objects, features and advantages of this invention will become more apparent by reference to the following detailed description of the invention taken in conjunction with the accompanying drawings, wherein:

FIG. 1 is a cross-sectional view illustrating a semiconductor device of the first embodiment of the present invention;

FIG. 2 is a cross-sectional view illustrating a method for producing the semiconductor device of the first embodiment of the present invention;

FIG. 3 is a cross-sectional view illustrating the method for producing the semiconductor device of the first embodiment of the present invention;

FIG. 4 is a cross-sectional view illustrating the method for producing the semiconductor device of the first embodiment of the present invention;

FIG. 5 is a cross-sectional view illustrating the method for producing the semiconductor device of the first embodiment of the present invention;

FIG. 6 is a schematic diagram illustrating an electroless plating method used in the method for producing the semiconductor device of the first embodiment of the present invention;

FIG. 7 is a cross-sectional view illustrating the method for producing the semiconductor device of the first embodiment of the present invention;

FIG. 8 is a cross-sectional view illustrating the method for producing the semiconductor device of the first embodiment of the present invention;

FIG. 9 is a cross-sectional view illustrating the method for producing the semiconductor device of the first embodiment of the present invention;

FIG. 10 is a cross-sectional view illustrating a semiconductor device according to the second embodiment of the present invention;

FIG. 11 is a cross-sectional view illustrating a method for producing the semiconductor device according to the second embodiment of the present invention;

FIG. 12 is a cross-sectional view illustrating the method for producing the semiconductor device according to the second embodiment of the present invention;

FIG. 13 is a cross-sectional view illustrating the method for producing the semiconductor device according to the second embodiment of the present invention;

FIG. 14 is a cross-sectional view illustrating a conventional semiconductor device; and

FIG. 15 is a cross-sectional view illustrating a conventional semiconductor device.

### DETAILED DESCRIPTION OF THE INVENTION

The present invention will now be described with reference to the drawings.

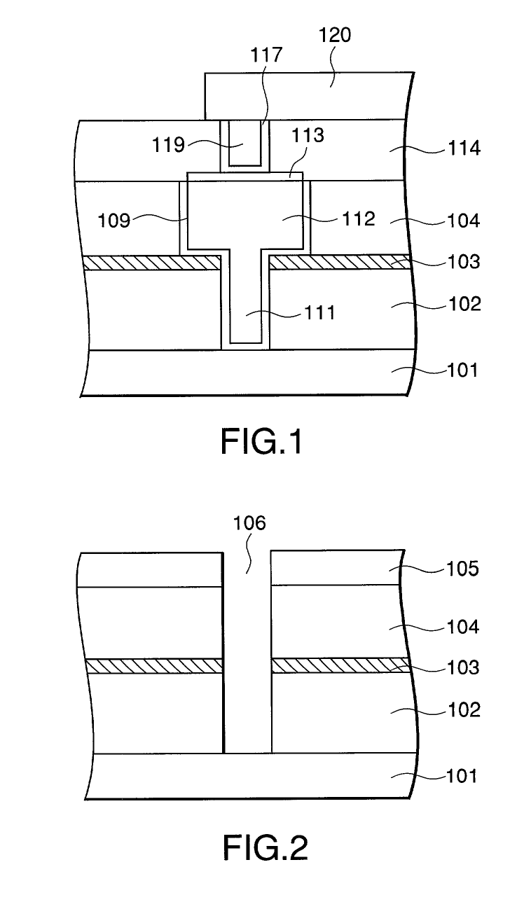

FIG. 1 is a cross-sectional view illustrating a structure of a semiconductor device of the first embodiment of the present invention.

In the semiconductor device of the present embodiment, a silicon oxide film 102 as a first interlayer insulation film is provided on a semiconductor substrate 101 on which elements such as transistors and an underlying interconnect have been formed. A connection 111 made of Cu is formed therein so as to reach the active elements and the underlying interconnect. A Cu interconnect layer 112 is embedded in a groove which is provided in an overlying silicon oxide film 10 4 as a second interlayer insulation film. A TaN film 109 as a first barrier metal layer for preventing Cu in an interconnect layer from diffusing into a silicon oxide film is provided between the connection 111 and the silicon oxide film 102 and between the Cu interconnect layer 112 and the silicon oxide film 104. An oxidization-resistant metal film, e.g., an Au layer 113, is formed on the upper surface of the Cu interconnect layer 112, thereby preventing Cu in the interconnect layer from diffusing into the silicon oxide film. The Au layer 113, being made of Au having both a low relative dielectric constant and a low electric resistance, has an effect of preventing the interconnect propagation delay and reducing the resistance value of the interconnect as a whole.

FIG. 2 to FIG. 9 illustrate a method for producing the semiconductor device of the first embodiment of the present invention.

As illustrated in FIG. 2, the silicon oxide film silicon oxide film 102, being the first interlayer insulation film, is deposited by a CVD method to a thickness of 100 nm to 800 nm, e.g., 600 nm, on the semiconductor substrate 101 on which elements such as transistors and an underlying interconnect have been formed. Then, a silicon nitride film 103 to be an etching stopper film is formed by a CVD method to a thickness of 20 to 100 nm. Then, the silicon oxide film 104, being the second interlayer insulation film, is deposited by a CVD method to a thickness of 100 nm to 800 nm, e.g., 400 nm. Then, the silicon oxide film 104, the silicon nitride film 103 and the silicon oxide film 102 are etched using a patterned photoresist 105 as a mask, thereby forming a through hole 106 reaching the elements and the underlying interconnect.

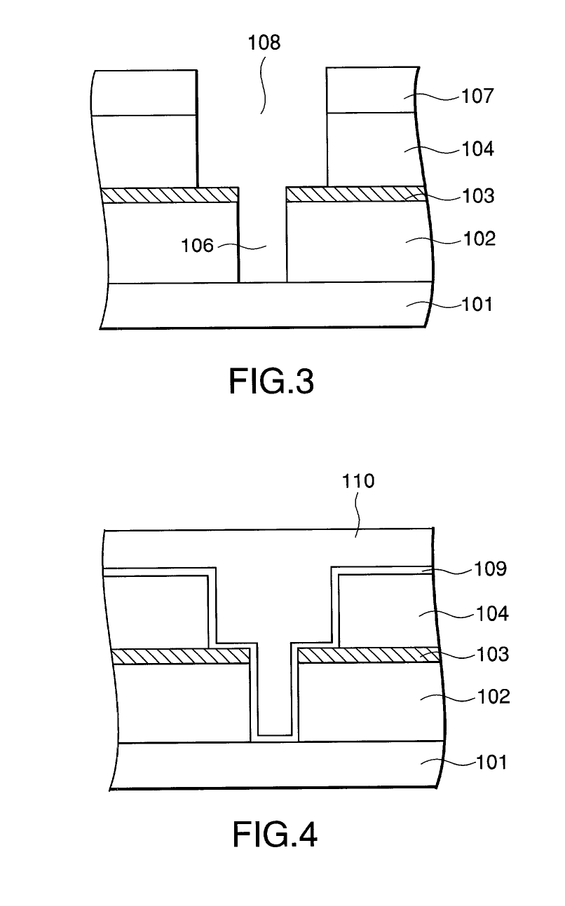

Then, as illustrated in FIG. 3, a groove 108 having a shape conforming to that of the Cu interconnect layer is formed in the silicon oxide film 104 by an etching process using a patterned photoresist 107 as a mask and using the silicon nitride film 103 as an etching stopper film.

Then, as illustrated in FIG. 4, the TaN film 109 as the first barrier metal layer for preventing Cu in the interconnect layer from diffusing into the silicon oxide films 102 and 104 is formed by a sputtering method to a thickness of 20 nm to 100 nm, e.g., 30 nm. The first barrier metal layer may alternatively be a Ta film. Then, Cu is sputtered by a sputtering method to a thickness of about 100 to 200 nm on the inner surface of the through hole 106 and the inner surface of the groove 108 having a shape conforming to that of the interconnect layer. Then, a Cu layer 110 is deposited by an electroplating method across the entire wafer surface so as to fill the through hole 106 and the groove 108 having a shape conforming to that of the interconnect layer. The electroplating method may be as follows. As illustrated in FIG. 6, a semiconductor substrate 3002 is immersed in a CuSO4 bath 3001, and an electric field is applied between the semiconductor substrate 3002 and an electrode 3003 so as to precipitate the Cu layer 110 onto the sputtered Cu layer using the sputtered Cu film as a power feeding layer. The Cu layer deposited on the silicon oxide film 104 has a thickness of 100 nm to 600 nm, e.g., 500 nm.

While the Cu layer can be deposited by a sputtering method, it is more preferred to use an electroplating method for the good filling property.

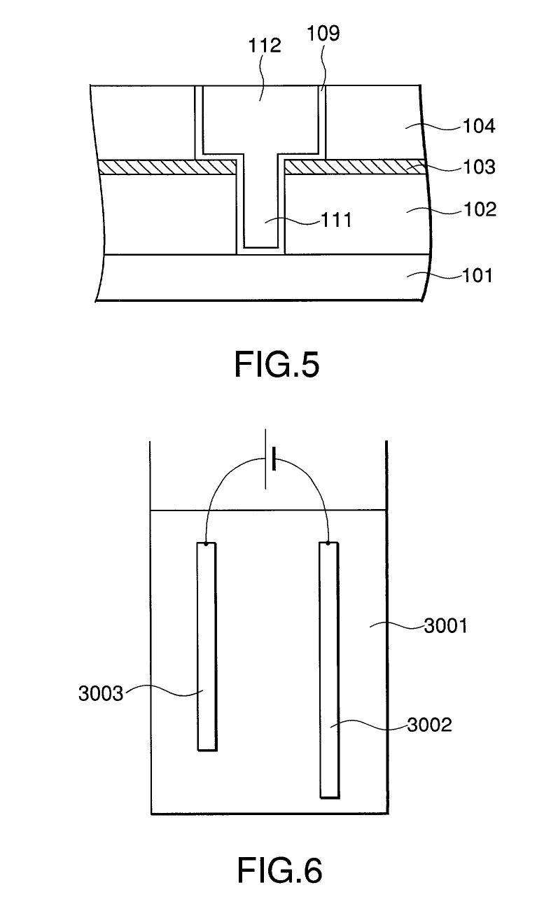

Then, as illustrated in FIG. 5, the Cu layer 110 and the TaN film 109 formed on the silicon oxide film 104 are polished away by a CMP method.

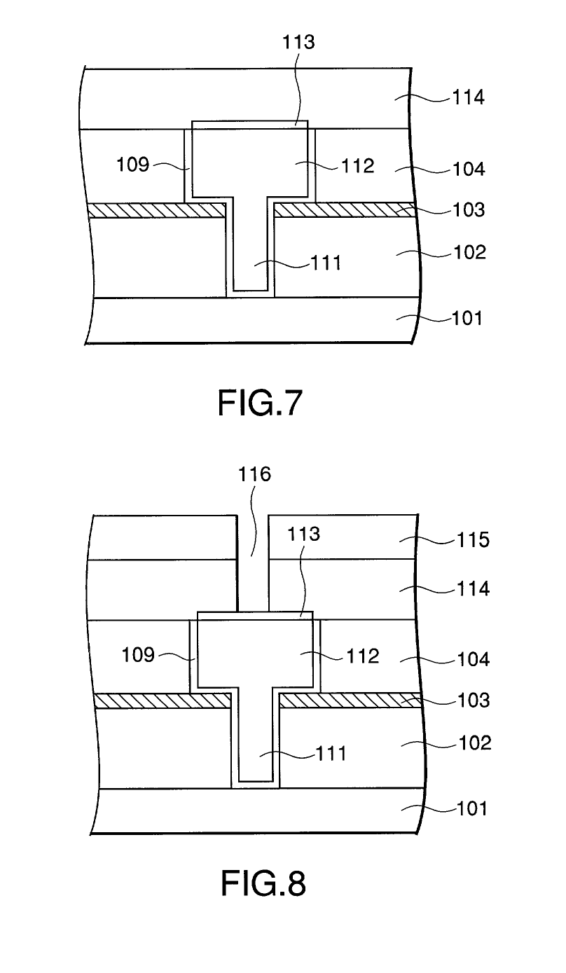

Then, as illustrated in FIG. 7, the Au layer 113 is formed by an electroless Au plating method on the Cu interconnect layer 112. With an electroless plating method, the semiconductor substrate 101 on which the Cu interconnect layer 112 has been formed is put into an Au electroless plating trough so as to be immersed in an Au plating solution, thereby forming the Au layer 113 selectively on the surface of the Cu interconnect layer 112.

By using a plating method for the formation of the Au layer 113, it is possible to form the Au layer 113 selectively on the surface of the Cu interconnect layer 112. Alternatively, without using a plating method, an Au layer can be deposited by a sputtering method to a thickness of 10 nm to 100 nm across the entire surface of the substrate 101, and then the Au layer on the silicon oxide film 104 can be removed by an etching process using a photoresist as a mask, thereby forming the Au layer 113 only on the Cu interconnect layer 112. However, the use of a plating method provides an advantage of eliminating the need for a patterning step.

Then, as illustrated in FIG. 8, a silicon oxide film 114 as a third interlayer insulation film is deposited to a thickness of 100 nm to 800 nm, e.g., 600 nm. Then, the silicon oxide film 114 is etched using a patterned photoresist 115 as a mask, thereby forming a through hole 116 reaching the Au layer 113.

The etching is stopped when the surface of the Au layer 113 is exposed, ensuring that the surface of the Cu interconnect layer 112 is not exposed. Then, the photoresist 115 is removed by an oxygen plasma process.

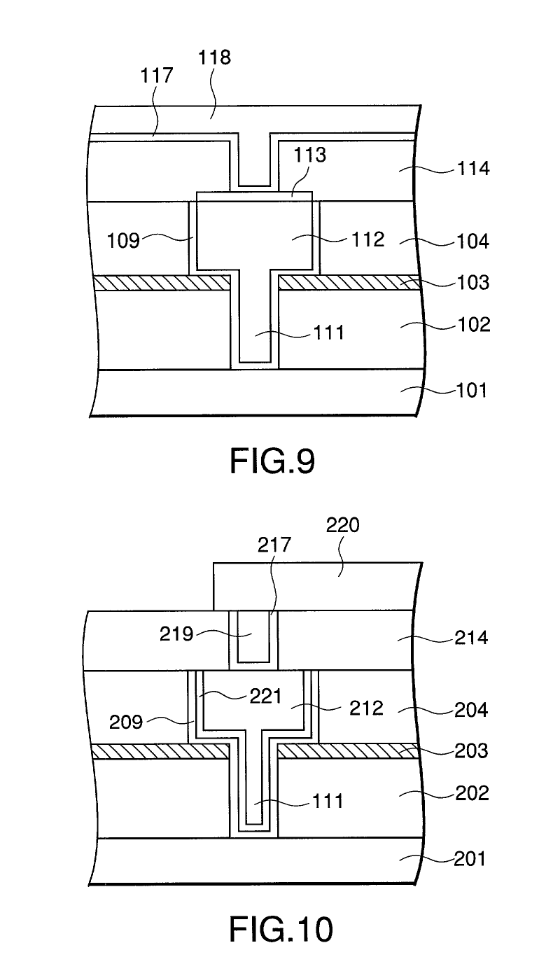

Then, by a method similar to the step illustrated in FIG. 4, a TaN film 117 is formed as a second barrier metal layer, and a Cu layer 118 is deposited by an electroplating method across the entire wafer surface so as to fill the through hole 116, as illustrated in FIG. 9. Then, by a method similar to the step illustrated in FIG. 5, the Cu layer 118 and the TaN film 117 on the silicon oxide film 114 are removed by a CMP method, thereby forming a Cu junction 119 which is electrically connected to the Cu interconnect layer 112 via the Au layer 113.

Then, an overlying interconnect 120 which is connected to the Cu junction 119 is formed on the silicon oxide film 114, thereby completing the multilayer interconnect structure as illustrated in FIG. 1. The overlying interconnect 120 is formed by a patterning process in the case of an Al interconnect, or by an embedding type process in the case of a Cu interconnect.

In the present embodiment, the connection 111, reaching the elements and the underlying interconnect on the substrate, and the Cu interconnect layer 112 are embedded at the same time in a single electroplating process using Cu. Alternatively, the connection 111 may be first formed in the silicon oxide film 102 using the method for forming the Cu junction 119 illustrated in FIG. 9, and then the silicon oxide film 104 is deposited, after which the Cu interconnect layer 112 is provided in the groove which has been formed in the silicon oxide film 104. In such a case, it is not necessary to form the silicon nitride film 103 as an etching stopper film on the silicon oxide film 102, whereby it is possible to reduce the relative dielectric constant of the interlayer insulation film as a whole. However, the formation in a single electroplating process as illustrated in the present embodiment is preferred for the advantage that it requires only one CMP step for Cu.

In the present embodiment, a silicon oxide film is used for the first, second and third interlayer insulation films. Alternatively, a fluorine-containing silicon oxide film whose relative dielectric constant is lower than that of a silicon oxide film, an HSQ (Hydrogen Silsesquioxane) film, a carbon-containing silicon oxide film, a porous oxide film, an organic film (a film made of CH or CHF), etc., may be used.

In the present embodiment, the silicon oxide film 114 is provided on the Au layer 113 as the third interlayer insulation film, as illustrated in FIG. 1. Alternatively, before depositing the silicon oxide film 114, an SiON film whose relative dielectric constant is lower than that of a silicon nitride film may be deposited to a thickness of 10 nm to 100 nm, and the silicon oxide film 114 may be formed thereon.

In the present embodiment, an Au layer, being a conductive film which is not easily oxidized, is formed as a Cu diffusion preventing film on the Cu interconnect layer. Then, when a through hole connected to the Cu interconnect layer is formed in the overlying interlayer insulation film by performing an etching process using a photoresist as a mask, the etching is stopped by the Au layer, which is a conductive film, whereby it is possible to perform an oxygen plasma process, which is a photoresist removing step, without exposing the upper surface of the Cu interconnect layer. Therefore, it is ensured that the Cu interconnect layer is not oxidized, and it is possible to keep the interconnect resistance low.

Also in the case where the photoresist is removed by a wet removing process using a removing solution such as amine, the bottom of the through hole is the Au layer, and the Cu interconnect layer is not exposed. Since an Au layer has a good resistance against chemicals such as an alkaline substance, it does not react with the removing solution in a wet removing process. Thus, it is possible to prevent defects of the Cu interconnect layer such as compound formation, dissolution, disconnection, etc.

Moreover, since the Au layer is not easily oxidized, a silicon oxide film or an SiON film whose relative dielectric constant is lower than that of a silicon nitride film can be deposited, instead of a silicon nitride film whose relative dielectric constant is high, as the interlayer insulation film 114 to be formed as a layer overlying the Cu interconnect layer, i.e., as the interlayer insulation film 114 to be formed on the surface of the Au layer. These films may possibly oxidize the material on the surface because they introduce an oxidizing gas along with a material gas during deposition by a CVD method. In the present embodiment, however, an Au layer, which is not easily oxidized, is provided on the surface, whereby it is ensured that the underlying interconnect layer is not oxidized. In the present embodiment, by using a silicon oxide film or an SiON film as an interlayer insulation film, it is possible to reduce the fringe effect between adjacent interconnects and to reduce the signal propagation delay.

Moreover, since an Au layer itself has a low relative dielectric constant, it is possible to improve the interconnect propagation speed as compared to a case where a silicon nitride film is formed on the interconnect layer.

Furthermore, as compared to a silicon nitride film, an Au layer has a sufficient Cu diffusion preventing effect.

FIG. 10 is a cross-sectional view illustrating a structure of a semiconductor device of the second embodiment of the present invention.

In the semiconductor device of the present embodiment, as in the semiconductor device of the first embodiment, a silicon oxide film 202 as a first interlayer insulation film is provided on a semiconductor substrate 201 on which elements such as transistors and an underlying interconnect have been formed, and a connection 211 made of an alloy of Cu and Ni is formed in the silicon oxide film 202. A Cu/Ni alloy layer 212 is further embedded in a silicon oxide film 204 as a second interlayer insulation film. A TaN film 209 as a first barrier metal layer for preventing Cu in an interconnect layer from diffusing into a silicon oxide film is provided between the connection 211 and the silicon oxide film 202 and between the Cu/Ni alloy layer 212 and a Cu film 221 and the silicon oxide film 204.

A difference between the semiconductor device of the present embodiment and that of the first embodiment is that the interconnect layer is made of the Cu/Ni alloy layer 212. The alloy layer 212 may be made of an alloy of Cu and a metal which is more easily oxidized than Cu. Metals which are more easily oxidized than Cu include Al, Ti, Ni, etc. An alloy of such a metal and Cu is used.

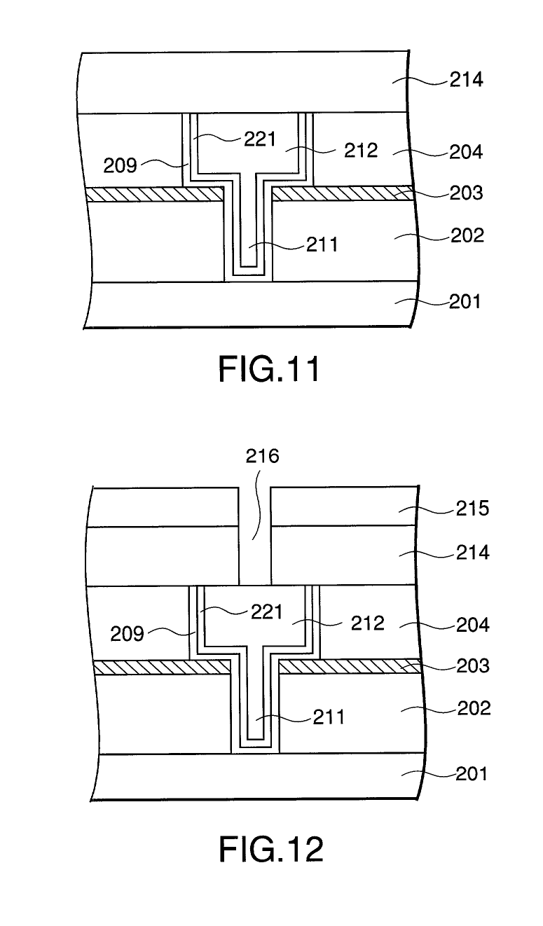

FIG. 11 to FIG. 13 illustrate a method for producing the semiconductor device of the second embodiment of the present invention.

First, as in the production method of the first embodiment illustrated in FIG. 2, the silicon oxide film 202, a silicon nitride film 203 to be an etching stopper film, and the silicon oxide film 104 as the second interlayer insulation film are deposited on the silicon substrate 201 on which elements such as transistors and an underlying interconnect have been formed, and the silicon oxide film 204, the silicon nitride film 203 and the silicon oxide film 202 are etched so as to form a through hole 206 reaching the elements and the underlying interconnect.

Then, as in the method illustrated in FIG. 3, a groove 208 having a shape conforming to that of the Cu interconnect layer is formed in the silicon oxide film 204 by an etching process using the silicon nitride film 203 as an etching stopper film. Then, as in the method illustrated in FIG. 4, the TaN film 209 is formed as the first barrier metal layer for preventing Cu in the interconnect layer from diffusing into the silicon oxide films 202 and 204.

Then, as illustrated in FIG. 11, the Cu film 221 is formed by a sputtering method to a thickness of 50 nm to 200 nm, e.g., 200 nm. Then, the Cu/Ni alloy layer 212 is precipitated by an electroplating method across the entire wafer surface so as to fill the through hole 206 and the groove 208 having a shape conforming to that of the interconnect layer. The electroplating method may be as follows. The semiconductor substrate 201 is immersed in a plating solution in which Cu or Ni ions exist so as to precipitate the Cu/Ni alloy layer 212 using the sputtered Cu film 221 as a power feeding layer.

Then, as in the method illustrated in FIG. 5, the Cu/Ni alloy layer 212 and the TaN film 209 formed on the silicon oxide film 204 are polished away by a CMP method, thereby forming the Cu/Ni alloy layer 212.

In order to increase the Cu content of the Cu/Ni alloy layer 212, the applied current density used in plating can be set to be as small as 1 A/dm² or less. In order to increase the Ni content, the applied current density can be set to a high value. When the Ni content is increased, the resistance increases, but the effect of preventing Cu in the Cu/Ni alloy layer 212 from being oxidized is improved.

Then, as illustrated in FIG. 11, a silicon oxide film 214 as a third interlayer insulation film is deposited to a thickness of 100 nm to 800 nm, e.g., 600 nm. The silicon oxide film 214 is etched using a patterned photoresist 215 as a mask so as to form a through hole 216 reaching the alloy layer 212.

The etching is stopped when the surface of the Cu/Ni alloy layer 212 is exposed. Then, the photoresist 215 is removed by an oxygen plasma process.

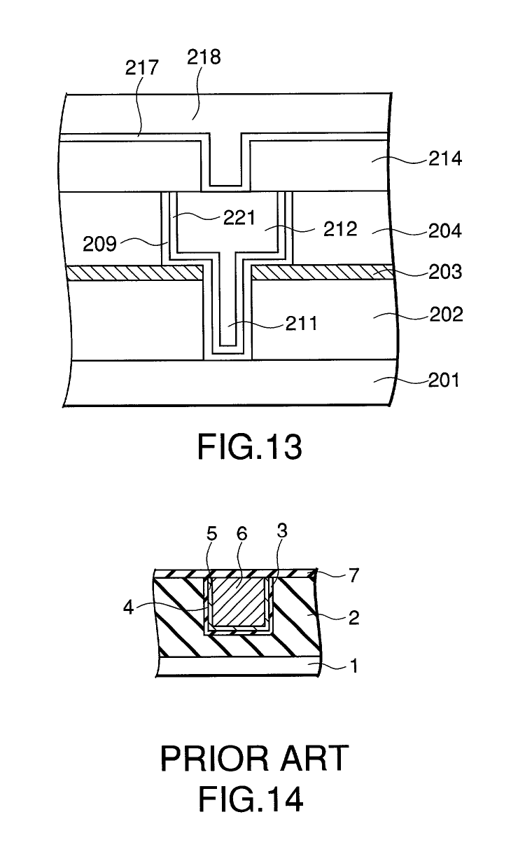

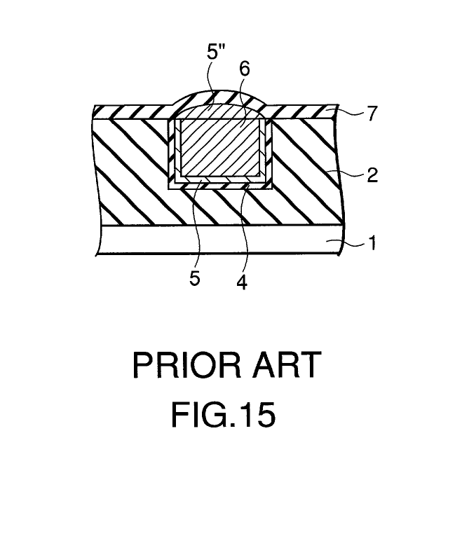

Then, as in the method illustrated in FIG. 4, a TaN film 217 is formed as a second barrier metal layer, and a Cu layer 218 is deposited by an electroplating method across the entire wafer surface so as to fill the through hole 216, as illustrated in FIG. 13. Then, the Cu layer 218 and the TaN film 217 on the silicon oxide film 214 are removed by a CMP method, thereby forming a Cu junction 219 which is electrically connected to the Cu/Ni alloy layer 212.

Then, an overlying interconnect 220 which is connected to the Cu junction 219 is formed on the silicon oxide film 214, thereby completing the multilayer interconnect structure as illustrated in FIG. 10.

Also in the present embodiment, as in the first embodiment, the connection 211 may be first formed in the silicon oxide film 202 using the method for forming the Cu junction 219 illustrated in FIG. 13, and then the silicon oxide film 204 is deposited, after which the Cu/Ni alloy layer 212 is provided in the groove which has been formed in the silicon oxide film 204.

Also in the present embodiment, a fluorine-containing silicon oxide film whose relative dielectric constant is lower than that of a silicon oxide film, an HSQ film, a carbon-containing silicon oxide film, a porous oxide film, an organic film, etc., may be used for the first, second and third interlayer insulation films.

Also in the present embodiment, a silicon nitride film having a thickness of 10 nm to 100 nm may be formed before depositing the silicon oxide film 214. Moreover, an SiON film whose relative dielectric constant is lower than that of a silicon nitride film may be deposited instead of a silicon nitride film, and the silicon oxide film 214 may be formed on the SiON film.

While a Cu/Ni alloy is used for the alloy layer 212 in the present embodiment, any alloy of Cu and a metal which is more easily oxidized than Cu and which can be precipitated together with Cu in a plating process can be used. Electrochemical equations for precipitation in the case where a Cu/Ni alloy layer is used are shown below. An alloy layer made of a combination of metals such as Cu and Ni which have close values of standard electrode potential as shown below is used.

Cu²⁺+2e⁻=Cu+0.34 V (Equation 1)

Ni²⁺+2e⁻=Ni+0.24 V (Equation 2)

In the present embodiment, the alloy layer 212 of Cu and a metal which is more easily oxidized than Cu is used as the interconnect layer. Then, when a through hole which is connected to the interconnect layer is formed in the overlying interlayer insulation film by an etching process using a photoresist as a mask, the etching is stopped when the Cu/Ni alloy layer 212 is exposed. Then, an oxygen plasma process, which is a photoresist removing step, is performed. In the ashing step, Ni in the Cu alloy layer 212, which is more easily oxidized than Cu, is selectively oxidized, whereby it is possible to suppress oxidization of Cu itself. As a result, it is possible to keep the interconnect resistance of the interconnect layer 212 low.

Moreover, the interconnect layer 212 is made of an alloy of Cu and a metal which is more easily oxidized than Cu so as to prevent Cu in the interconnect layer from being oxidized. Therefore, a silicon oxide film or an SiON film whose relative dielectric constant is lower than that of a silicon nitride film can be deposited, instead of a silicon nitride film whose relative dielectric constant is high, as the interlayer insulation film to be formed on the interconnect layer. These films may possibly oxidize the material on the surface because they introduce an oxidizing gas along with a material gas during deposition by a CVD method. In the present embodiment, however, an alloy layer is exposed on the surface, whereby it is ensured that Ni in the interconnect layer is selectively oxidized and that Cu is not oxidized. Thus, in the present embodiment, by using a silicon oxide film or an SiON film as an interlayer insulation film, it is possible to reduce the fringe effect between adjacent interconnects and to reduce the signal propagation delay.

Moreover, since the alloy layer 212 has a lower relative dielectric constant than that of a silicon nitride film which is conventionally provided on a Cu interconnect layer, it is possible to better prevent the delay of the interconnect propagation speed than in the prior art.

Furthermore, as compared to a silicon nitride film, the alloy layer 212 has a sufficient Cu diffusion preventing effect.

In the present invention, an Au layer, being a conductive film which is not easily oxidized, is formed as a Cu diffusion preventing film on the Cu interconnect layer. Then, when a through hole connected to the Cu interconnect layer is formed in the overlying interlayer insulation film by performing an etching process using a photoresist as a mask, the etching is stopped by the Au layer, which is a conductive film. Thus, it is possible to perform an oxygen plasma process, which is a photoresist removing step, without exposing the upper surface of the Cu interconnect layer. Therefore, it is possible to prevent the Cu interconnect layer from being oxidized, and it is possible to keep the interconnect resistance low.

Moreover, since an Au layer, which is not easily oxidized, is provided on the Cu interconnect layer, a film such as SiON whose relative dielectric constant is lower than that of SiN can be formed as the overlying interlayer insulation film without oxidizing the Cu interconnect layer, whereby it is possible to reduce the interconnect propagation delay due to the fringe effect.

Furthermore, in the present invention, a Cu film and an alloy layer of Cu and a metal which is more easily oxidized than Cu is used as the interconnect layer. Then, when a through hole which is connected to the Cu interconnect layer is formed in the overlying interlayer insulation film by an etching process using a photoresist as a mask, the etching is stopped when the alloy layer, which is a conductive film, is exposed. Then, in an oxygen plasma process, which is a photoresist removing step, only a metal in the Cu alloy layer, which is more easily oxidized than Cu, is selectively oxidized, whereby it is possible to prevent Cu in the interconnect layer from being oxidized and to keep the interconnect resistance low.

Moreover, since a Cu film and an alloy layer of Cu and a metal which is more easily oxidized than Cu are used for the interconnect layer, a film such as SiON whose relative dielectric constant is lower than that of SiN can be formed as the overlying interlayer insulation film without oxidizing Cu in the interconnect layer, whereby it is possible to reduce the interconnect propagation delay due to the fringe effect.

Although the invention has been described with reference to specific embodiments, this description is not meant to be construed in a limiting sense. Various modifications of the disclosed embodiments will become apparent to persons skilled in the art upon reference to the description of the invention. It is therefore contemplated that the appended claims will cover any modifications or embodiments as fall within the true scope of the invention.

What is claimed is:

1. A method for producing a semiconductor device, comprising the steps of:
forming an interlayer insulation film on a semiconductor substrate; forming a groove in said interlayer insulation film; forming a metal interconnect layer in said groove; forming an oxidization-resistant metal layer on an upper surface of said metal interconnect layer by an electroless plating method; and forming an oxygen-containing insulation film on an upper surface of said metal layer.

2. A method for producing a semiconductor device according to claim 1, wherein said metal interconnect layer is made of a metal film containing copper, and said metal layer is made of a metal film containing gold.

3. A method for producing a semiconductor device according to claim 1, further comprising the steps of: forming a through hole reaching said metal interconnect layer in said insulation film by an etching process using a photoresist as a mask; and removing said photoresist.

4. A method for producing a semiconductor device, comprising the steps of:
forming an interlayer insulation film on a semiconductor substrate; forming a groove in said interlayer insulation film; forming a first metal film in said groove; forming an alloy layer by an electroplating method on an upper surface of said first metal film so as to fill said groove; and forming an oxygen-containing insulation film on an upper surface of said alloy layer,
wherein said alloy layer is made of an alloy of a first metal which is used for said first metal film and a second metal which is more easily oxidized than said first metal.

5. A method for producing a semiconductor device according to claim 4, wherein said first metal film is made of a metal film containing copper, and said alloy layer is made of a metal film containing copper and nickel.

6. A method for producing a semiconductor device according to claim 4, further comprising the steps of: forming a through hole reaching said alloy layer in said insulation film by an etching process using a photoresist as a mask; and removing said photoresist.
